(19) United States
(12) Patent Application Publication
(10) Pub. No.: US 2008/0083957 A1
(43) Pub. Date: Apr. 10, 2008

(54) MICRO-ELECTROMECHANICAL SYSTEM PACKAGE

(76) Inventors: Wen-Chieh Wei, Taichung (TW); Hong-Ching Her, Taichung (TW); Shih-Chin Gong, Taipei (TW); Chih-Wei Chang, Taya Hsiang (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/539,025

(22) Filed: Oct. 5, 2006

(51) Int. Cl. H01L 29/84

(52) U.S. Cl. 257/415

(57) ABSTRACT

A micro-electromechanical system package includes a substrate, a group of components, isolative stuff and a conductive shield. The substrate is made with an upper face and a lower face. The group is mounted on the upper face of the substrate. The isolative stuff seals the group and the upper face of the substrate, thus protecting the group from moisture. The conductive shield covers the isolative stuff, thus protecting the group from electromagnetic interference.

### BACKGROUND OF INVENTION

1. Field of Invention

The present invention relates to a micro-electromechanical system (“MEMS”) package and, more particularly, to a MEMS package that is protected from moisture and electromagnetic interference.

2. Related Prior Art

Disclosed in U.S. Pat. No. 6,781,231 is a conventional MEMS package 10 including a substrate 14, a plurality of components 12 installed on the substrate 14 and a cover 20 installed on the substrate 14 for shielding the components 12. The cover 20 consists of an external cup 25a and an internal cup 25b installed within the external cup 25a. The cover 20 is used as a shield from electro-magnetic interference. The cover 20 and the substrate 14 define a housing 22. The cover 20 includes a plurality of acoustic ports 44 each including an environmental barrier layer 48.

Several problems have been encountered in the use of the MEMS package 10. Firstly, the housing 22 contains air that inevitably includes moisture. When the micromechanical system package 10 is moved from a cool area to a warm area such as from an air-conditioned room to the outside, the components 12 and the cover 20 remain cool so that the moisture condenses on the components 12 and/or the cover 20. The components 12 and/or the cover 20 may be damaged because of the moisture.

Secondly, the housing 22, which is a metal cup-shaped element, keeps the moisture therein, and the moisture jeopardizes the isolation of the components 12 from the cover 20 and the isolation of the components 12 from one another. Therefore, the performance of the MEMS package 10 is affected.

Thirdly, the micro-electromechanical system package 10 is bulky for including the cover 20.

Fourthly, the manufacturing process by using the cover 20 is different from typical processes for manufacturing integrated circuits.

Therefore, the present invention is intended to obviate or at least alleviate the problems encountered in prior art.

### SUMMARY OF INVENTION

A micro-electromechanical system package includes a substrate, a group of components, isolative stuff and a conductive shield. The substrate is made with an upper face and a lower face. The group is mounted on the upper face of the substrate. The isolative stuff seals the group and the upper face of the substrate, thus protecting the group from moisture. The conductive shield covers the isolative stuff, thus protecting the group from electromagnetic interference.

An advantage of the micro-electromechanical system package according to the present invention is the protection of the group from moisture.

Another advantage of the micro-electromechanical system package according to the present invention is the protection of the group from electromagnetic interference.

Other advantages and features of the present invention will become apparent from the following description referring to the drawings.

### BRIEF DESCRIPTION OF DRAWINGS

The present invention will be described through detailed illustration of two embodiments referring to the drawings.

FIG. 1 is a cross-sectional view of a micro-electromechanical system package according to the first embodiment of the present invention.

FIG. 2 is a cross-sectional view of a micro-electromechanical system package according to the second embodiment of the present invention.

FIG. 3 is a cross-sectional view of several micro-electromechanical system packages undergoing a packaging process.

### DETAILED DESCRIPTION OF EMBODIMENTS

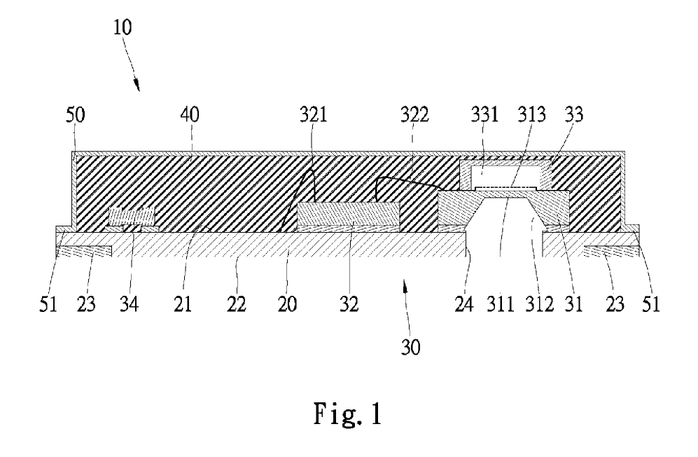

Referring to FIG. 1, there is shown a micro-electromechanical system (“MEMS”) package 10 according to a first embodiment of the present invention. The MEMS package 10 includes a substrate 20, a group 30 of components mounted on the substrate 20, isolative stuff 40 provided on the substrate 20 and the group 30 and a conductive shield 50 for covering the substrate 20 and the isolative stuff 40.

The substrate 20 is made with an upper surface 21 and a lower surface 22. All of the group 30, the isolative stuff 40 and the conductive shield 50 are mounted on the upper surface 21 of the substrate 20. Solder pads 23 are formed on the lower surface 22 of the substrate 20 for mounting on a printed circuit board or any other carrier. Via the solder pads 23, the substrate 20 is electrically connected to a circuit board of an electronic device that incorporates the MEMS package 10. The substrate 20 defines a sound aperture 24 via which sound travels.

The group 30 includes a plurality of components for executing the functions of the MEMS package 10. Preferably, the group 30 includes a MEMS microphone 31, an application specific integrated circuit 32 (“ASIC 32”) and a passive element 34. The MEMS microphone 31 is mounted on the upper face 21 of the substrate 20. The MEMS microphone 30 includes a diaphragm 311, a chamber 312, and a perforated back plate 313. The chamber 312 is in communication with the sound aperture 24, and the diaphragm 311 is aligned with the sound aperture 24. The diaphragm 311 and the perforated back plate 313 form an electrical capacitor. Sound reaches and causes the diaphragm 311 to deflect in response to the pressure thereof. Thus, the capacitance of the MEMS microphone 30 varies.

A cover 33 is mounted on the MEMS microphone 31 so that a chamber 331 is defined by the cover 33 and the diaphragm 311. The chamber 331 allows the vibration produced by the diaphragm 311.

The ASIC 32 is mounted on the upper surface 21 of the substrate 20. The ASIC 32 is electrically connected to the substrate 20 by at least one wire 321. On the other hand, the ASIC 32 is electrically connected to the MEMS microphone 31 by at least one wire 322.

The passive element 34 is mounted on the upper face 21 of the substrate 20. The passive element 34 may be a capacitor, resistor or inductance.

In use, on receiving the sound, the MEMS microphone 31 generates the changes in the capacitance thereof. On receiving the changes in the capacitance, the ASIC 32 produces electric signals corresponding to the changes in the capacitance. The electric signals are passed through the passive element 34 while the fundamental characteristics thereof are not changed.

isolative stuff 40 is provided on the group 30 and the upper surface 21 of the substrate 20, thus completely sealing the group 30. In specific, all of the MEMS microphone 31, the ASIC 32 and the passive element 34 are sealed by the isolative stuff 40. Therefore, the group 30 is protected from moisture that would otherwise damage the group 30.

The isolative stuff 40 is made of a molding compound generally used during the packaging of integrated circuits. The dimensions, such as the thickness and area, of the isolative stuff 40 are determined according to the desired dimensions of the MEMS package 10.

The conductive shield 50 is mounted on the isolative stuff 40. The conductive shield 50 includes a rim 51 mounted on the upper face 21 of the substrate 20. The rim 51 is directly electrically connected to the electronic device. Hence, the conductive shield 50 protects the group 30 mounted on the upper surface 21 of the substrate 20 from electromagnetic interference. Preferably, the conductive shield 50 is provided by vacuum sputtering.

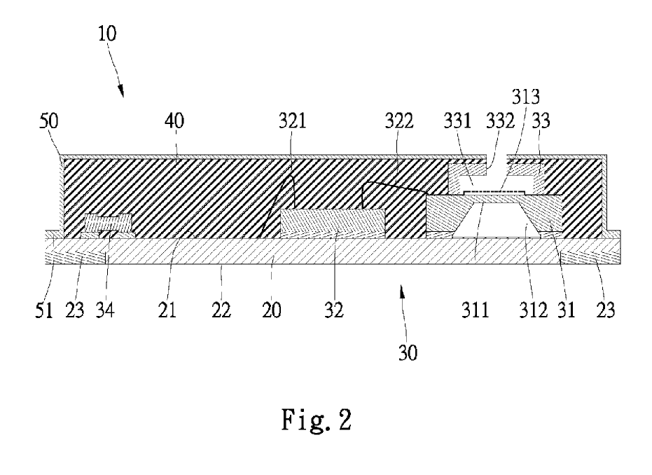

Referring to FIG. 2, there is shown a MEMS package according to a second embodiment of the present invention. The second embedment is like the first embodiment except defining a sound aperture 332 instead of the sound aperture 24. The sound aperture 332 is defined in the conductive shield 50, the isolative stuff 40 and the cover 33. Thus, the sound aperture 332 is in communication with the chamber 331. Hence, sound reaches the diaphragm 311 through the chamber 331 and the sound aperture 332. Sound reaches and causes the diaphragm 311 to deflect in response to the pressure thereof. Thus, the capacitance of the MEMS microphone 30 varies.

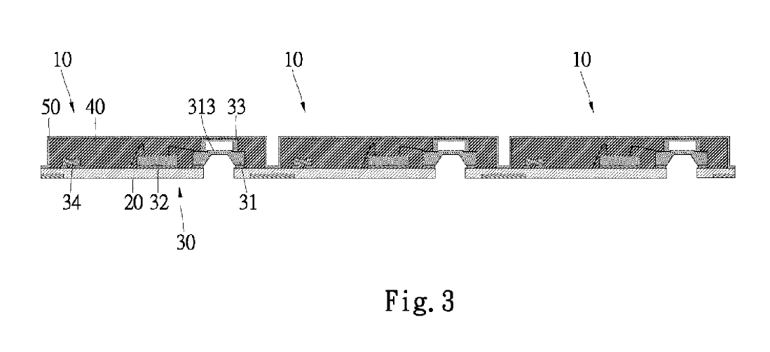

Referring to FIG. 3, there are shown several micro-electromechanical system packages during an array-type packaging process. The MEMS package according to the invention is suitable for batch production. Groups 30 are mounted on substrates 20. Then, bonding is conducted. The isolative stuff 40 is provided on the groups 30 and the substrates 20. Finally, conductive shields 50 are provided on the isolative stuff 40 and the substrate 20 by vacuum sputtering. The array-type packaging process is like what is typically used to produce integrated circuits. Finally, the MEMS packages 10 are cut from one another.

The MEMS package according to the present invention exhibits several advantages. Firstly, by the isolative stuff, the components are sealed and protected from moisture that would otherwise be entailed by change in temperature.

Secondly, it can be made as small as possible since the dimensions of the isolative stuff are controlled according to various needs.

Thirdly, the components are protected from electromagnetic interference by the conductive shield provided on the isolative stuff and connected to the electronic device that incorporates the MEMS package.

The present invention has been described via the detailed illustration of the embodiments. Those skilled in the art can derive variations from the embodiments without departing from the scope of the present invention. Therefore, the embodiments shall not limit the scope of the present invention defined in the claims.

What is claimed is:

1. A micro-electromechanical system package comprising:
a substrate comprising an upper surface and a lower surface;
a group of components mounted on the upper surface of the substrate;
isolative stuff for sealing the group and the upper surface of the substrate, thus protecting the group from moisture; and
a conductive shield for covering the isolative stuff, thus protecting the group from electromagnetic interference.

2. The micro-electromechanical system according to claim 1 wherein the group comprises a micro-electromechanical system microphone and an application specific integrated circuit electrically connected to the micro-electromechanical system microphone.

3. The micro-electromechanical system according to claim 2 wherein the micro-electromechanical system microphone comprises a diaphragm and a perforated back plate mounted thereon and defines a lower chamber below the diaphragm and an upper chamber above the diaphragm so that the lower and upper chambers allow the vibration of the membrane.

4. The micro-electromechanical system package according to claim 3 wherein the substrate defines a sound aperture in communication with the lower chamber so that sound travels to the diaphragm through the lower chamber and the sound aperture.

5. The micro-electromechanical system according to claim 3 wherein the micro-electromechanical system microphone comprises a cover mounted on the membrane so that the upper chamber is defined by the cover and the membrane.

6. The micro-electromechanical system package according to claim 5 wherein the cover, the isolative shield and the conductive shield define a sound aperture in communication with the upper chamber so that sound travels to the membrane through the upper chamber and the sound aperture.

7. The micro-electromechanical system package according to claim 1 wherein the conductive shield comprises a rim mounted on the upper surface of the substrate.

8. The micro-electromechanical system package according to claim 7 wherein the rim is electrically connected to an electronic device that incorporates the micro-electromechanical system package.

9. The micro-electromechanical system package according to claim 8 wherein the substrate comprises a plurality of solder pads formed on the lower surface thereof for electrically connecting the substrate to the electronic device.

10. The micro-electromechanical system package according to claim 1 wherein the conductive shield is provided by vacuum sputtering.

11. The micro-electromechanical system package according to claim 1 wherein the isolative stuff is made of a molding compound.
